(19) United States
(12) Patent Application Publication
(10) Pub. No.: US 2011/0155196 A1
(43) Pub. Date: Jun. 30, 2011

(54) TENT CAPABLE OF POWER GENERATION

(76) Inventor: Tsung- Hsien Wu, Taipei City (TW)

(21) Appl. No.: 12/650,554

(22) Filed: Dec. 31, 2009

(51) Int. Cl. E04H 15/02; H01L 31/00

(52) U.S. Cl. 135/96; 136/256

(57) ABSTRACT

A tent capable of power generation essentially includes a tent body, a flexible solar cell, and an energy storage device, wherein the flexible solar cell is laid over the tent body. When the tent body is exposed to sunlight, the flexible solar cell absorbs the energy of sunlight and converts the light energy into electric energy, which is then stored in the energy storage device. Thus, the tent not only blocks sunlight but also generates electricity therefrom.

### BACKGROUND OF THE INVENTION

1. Technical Field

The present invention relates to a tent capable of power generation and, more particularly, to a tent capable of generating electricity from solar energy.

2. Description of Related Art

As people pay more and more attention to recreation, activities such as outings and camping have become increasingly popular, and the ideal sites for such activities are, for example, seashores, riversides, and mountain areas. To enhance the quality of leisure activities, the right equipment must be used. Therefore, not only do consumers place much emphasis on recreational equipment, but also manufacturers put a lot of effort into its development. Tents, in particular, are a solution to dwelling outdoors. On the other hand, certain electric appliances, such as cell phones, lighting apparatus, or heat dissipation apparatus, are necessary to increase the quality of outdoor life. Generally, small diesel generators are brought to the site and used as a power source of the electric appliances. However, diesel generators are disadvantaged by its noise, exhaust, and limited diesel storage and tend to lower travel quality significantly.

### BRIEF SUMMARY OF THE INVENTION

It is a primary objective of the present invention to provide a tent which essentially includes a tent body, a flexible solar cell, and an energy storage device, wherein the flexible solar cell is laid over the tent body. When the tent body is placed outdoors and exposed to sunlight, the flexible solar cell absorbs solar energy and converts the solar energy into electric energy, which is then stored in the energy storage device. Thus, the tent serves to block sunlight and generate electricity therefrom.

It is a secondary objective of the present invention to provide the foregoing tent, wherein the energy storage device is provided with at least one USB port for connecting with an external device and delivering the electric energy stored in the energy storage device to the external device, thereby providing necessary electricity to the external device.

### BRIEF DESCRIPTION OF THE SEVERAL VIEWS OF THE DRAWINGS

The invention as well as a preferred mode of use, further objectives, and advantages thereof will be best understood by referring to the following detailed description of an illustrative embodiment in conjunction with the accompanying drawings, in which:

FIG. 1 is a perspective view of the present invention;

FIG. 2 is an exploded perspective view of the present invention;

FIG. 3 is a schematic partial view of the present invention;

FIG. 4 is another schematic partial view of the present invention;

FIG. 5 is a perspective view of a preferred embodiment of the present invention; and

FIG. 6 is a partial view of the preferred embodiment of the present invention.

### DETAILED DESCRIPTION OF THE INVENTION

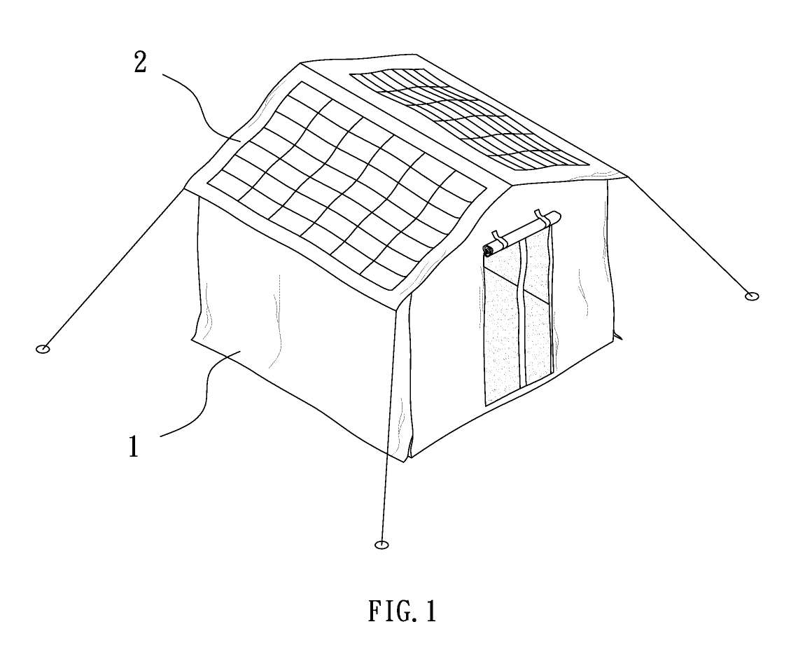

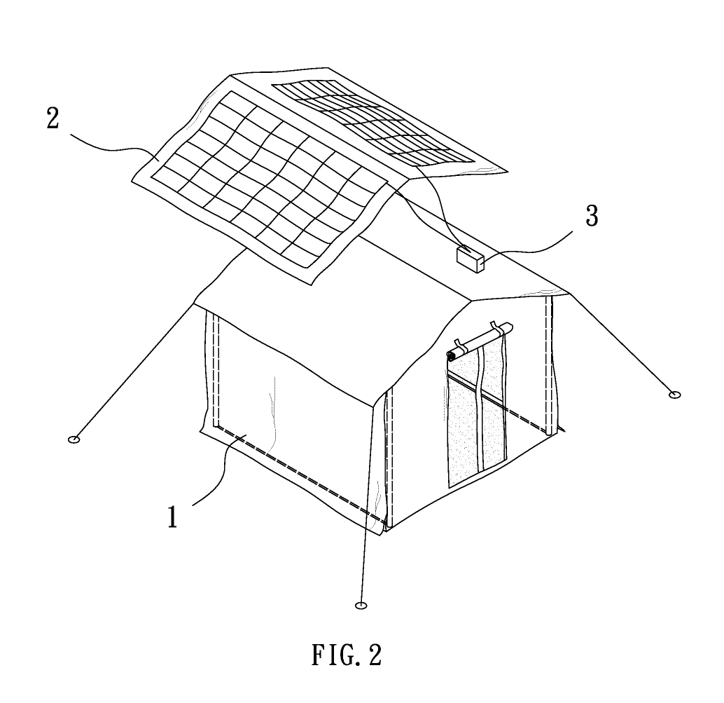

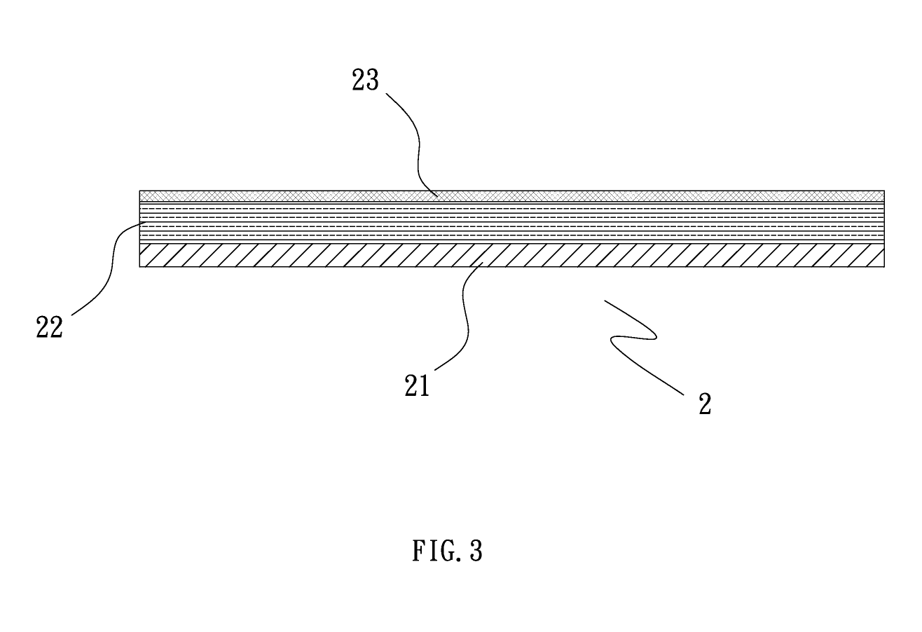

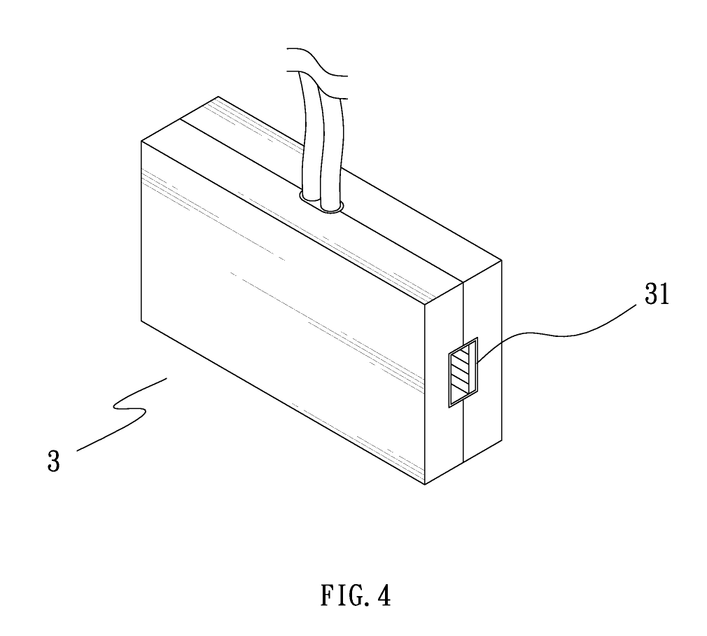

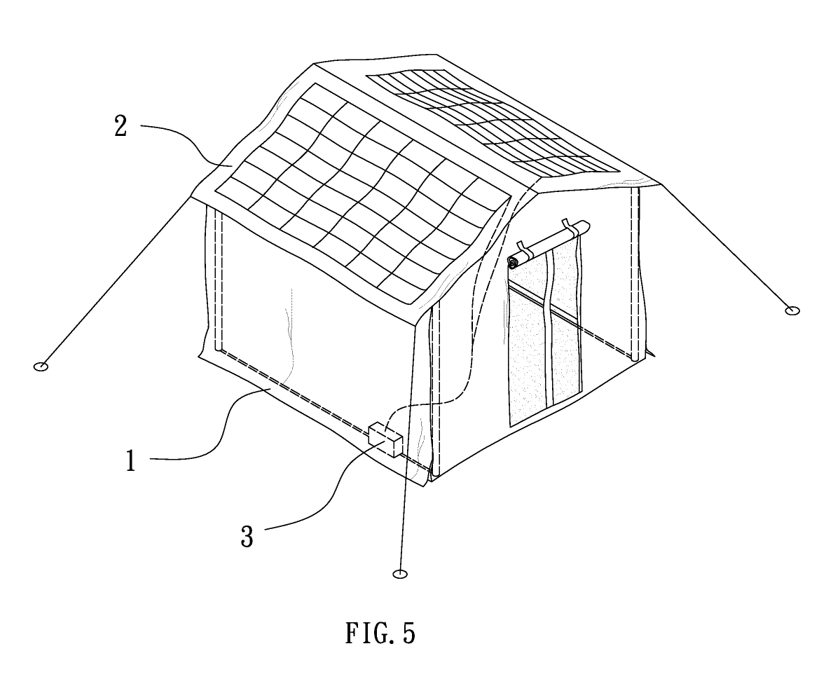

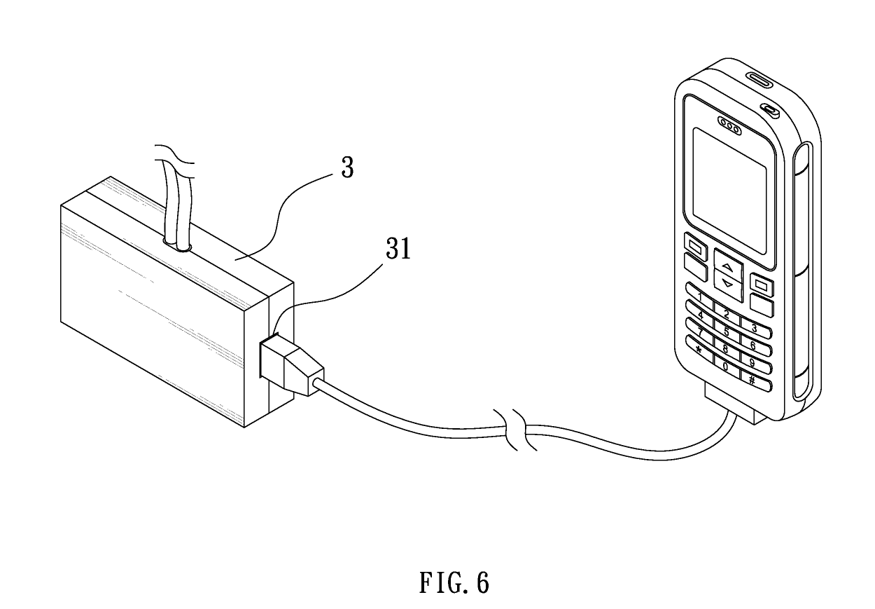

Referring to FIGS. 1 through 6, a tent capable of power generation according to the present invention includes a tent body 1, a flexible solar cell 2, and an energy storage device 3.

The flexible solar cell 2 is laid over the tent body 1 and configured to absorb solar energy and convert the solar energy into electric energy. Basically, the flexible solar cell 2 includes a pliable substrate 21 provided with a printed photovoltaic layer 22, and the printed photovoltaic layer 22 is further covered by a transparent protective layer 23. An example of the flexible solar cell 2 is the pliable solar cell developed by Fuji Electric Systems, wherein the pliable solar cell mainly has two layers, namely an upper layer and a lower layer. The upper-layer element is made of amorphous silicon and configured to absorb principally light of short wavelength. The lower-layer element, on the other hand, is an amorphous silicon-germanium film configured to absorb principally light of long wavelength. The pliable solar cell of Fuji Electric Systems uses a plastic substrate having a thickness of 50 μm, which is only 1/50 of a common glass substrate. The pliable solar cell has a combined thickness of no more than 1 mm and a photoelectric conversion rate higher than 8.2%.

The energy storage device 3 is a capacitor for storing the electric energy converted by the flexible solar cell 2 from solar energy. The capacitor can be transformed into an electric energy storage device such as a nickel-metal hydride battery, an alkaline battery, a lithium polymer battery, a mercury battery, a nickel-cadmium battery, or a lithium battery. Also, the energy storage device 3 is provided with at least one USB port 31.

The present invention is characterized by the combination of the flexible solar cell 2 and the tent body 1. The flexible solar cell 2 is lightweight, substantially unbreakable, and ready to integrate with other products, particularly non-planar device. Therefore, the flexible solar cell 2 can be easily used in conjunction with consumer electronics products, clothing, or leather products. In addition, the flexible solar cell 2 is highly heat-resistant, has relatively low demand for illuminance, can generate relatively more electricity, and is less susceptible to environmental factors.

According to the present invention, when the tent body 1 is placed outdoors and exposed to the sun, the flexible solar cell 2, which is laid over the tent body 1, absorbs solar energy and converts the solar energy into electric energy, which is stored in the energy storage device 3 for use at night, when there is no sunlight. To increase system reliability and power supply stability, a capacitor is used as the energy storage device 3. Furthermore, the energy storage device 3 is provided with at least one USB port 31 or electrical socket so that a cell phone, personal digital assistant (PDA), MP3 player, lighting apparatus, or other external devices can be connected to the USB port 31 and draw the electric energy stored in the energy storage device 3 through the USB port 31, so as to be supplied with necessary electricity.

Another advantage of the present invention is that, when the tent body 1 is placed outdoors and exposed to the sun, the flexible solar cell 2 laid over the tent body 1 not only serves to absorb solar energy and convert the solar energy into usable electric energy to be stored in the energy storage device 3 and subsequently drawn out to charge external devices in an outdoor setting, but also functions as a shield against sunlight and solar radiation so that a person inside the tent body 1 will not feel too hot. Besides, when the flexible solar cell 2 is absorbing solar energy and converting the solar energy into usable electric energy, an external device can be charged at the same time. The transparent protective layer 23, which is the top layer of the flexible solar cell 2, also prevents entry of insects and dust.

While the present invention is described herein by reference to the preferred embodiment, it is understood that the embodiment is not intended to limit the scope of the present invention, which is defined only by the appended claims.

What is claimed is:

1. A tent capable of power generation, essentially comprising:
a tent body;
a flexible solar cell laid over the tent body and configured to absorb solar energy and convert the solar energy into electric energy; and
an energy storage device for storing the electric energy converted by the flexible solar cell from the solar energy;
wherein the energy storage device is provided with a port for supplying electricity to an external device.

2. The tent capable of power generation as claimed in claim 1, wherein the flexible solar cell comprises a pliable substrate provided with a printed photovoltaic layer, and the printed photovoltaic layer is covered by a transparent protective layer.

3. The tent capable of power generation as claimed in claim 1, wherein the energy storage device is an electric energy storage device selected from the group consisting of a nickel-metal hydride battery, an alkaline battery, a lithium polymer battery, a mercury battery, a nickel-cadmium battery, and a lithium battery.

4. The tent capable of power generation as claimed in claim 1, wherein the energy storage device is provided with at least a USB port.
